(19) United States
(12) Patent Application Publication
(10) Pub. No.: US 2021/0187543 A1
(43) Pub. Date: Jun. 24, 2021

(54) FILM FORMING APPARATUS

(71) Applicant: Toshiba Mitsubishi-Electric Industrial Systems Corporation, Tokyo (JP)

(72) Inventor: Hiroyuki ORITA, Tokyo (JP)

(73) Assignee: Toshiba Mitsubishi-Electric Industrial Systems Corporation, Tokyo (JP)

(21) Appl. No.: 17/047,699

(22) PCT Filed: Jun. 8, 2018
(86) PCT No.: PCT/JP2018/022036

§ 371 Date: Oct. 15, 2020

(51) Int. Cl. B05D 1/02; B05B 7/16

(52) U.S. Cl. CPC B05D 1/02; B05B 7/164

(57) ABSTRACT

In the present invention, an infrared radiation apparatus is disposed at a position apart from a conveyor in a lower chamber. The infrared radiation apparatus performs heating treatment for a plurality of substrates placed on an upper surface of a belt by radiating infrared light upwardly from a plurality of infrared lamps. In a film forming chamber, a thin film is formed on the substrates placed on the upper surface of the belt by simultaneously performing the heating treatment of infrared radiation of the infrared radiation apparatus and mist spray treatment of a thin film forming nozzle.

### TECHNICAL FIELD

The present invention relates to a film forming apparatus that is used to manufacture an electronic device such as a solar battery and that forms a thin film on a substrate.

### BACKGROUND ART

As a method of forming a film on a substrate, the chemical vapor deposition (CVD) method has been known. However, the chemical vapor deposition method often requires film formation in a vacuum, and thus a large vacuum chamber, as well as a vacuum pump etc., needs to be used. Further, in the chemical vapor deposition method, there has been a problem in that using a substrate having a large area as a substrate to be subjected to film formation is difficult from a point of view of costs or the like. In view of this, a misting method, which enables film forming treatment in atmospheric pressure, has been drawing attention.

As a conventional technology related to a film forming apparatus using such a misting method, for example, there is a technology according to Patent Document 1.

In the technology according to the Patent Document 1, atomized source solution and reaction material are sprayed from a source solution ejection port and a reaction material ejection port that are provided on a bottom surface of a mist spray head unit including a mist spray nozzle etc. to a substrate disposed in an atmosphere. With such spraying, a film is formed on the substrate. Note that the reaction material refers to a material that contributes to a reaction with the source solution.

FIG. 3 is an explanatory diagram illustrating a schematic configuration of a conventional film forming apparatus. As illustrated in FIG. 7, on the upper surface of a substrate placing stage 30 being a substrate placing unit, a plurality of substrates 10 are placed.

The substrate placing stage 30 includes a suction mechanism 31 that performs vacuum suction. Using the suction mechanism 31, the substrate placing stage 30 can suck the entire back surface of each of the plurality of placed substrates 10 onto the upper surface of the substrate placing stage 30. Further, in the substrate placing stage 30, a heating mechanism 32 is provided below the suction mechanism 31. Using the heating mechanism 32, the substrate placing stage 30 can perform heating treatment on the plurality of substrates 10 placed on the upper surface of the substrate placing stage 30.

A thin film forming nozzle 1 (mist spray unit) performs mist spray treatment of spraying source mist MT downwardly from a spray port provided in a spray surface is. Note that the source mist MT is a mist obtained by atomizing a source solution. Using the thin film forming nozzle 1, the source mist MT can be sprayed in the atmosphere.

All of the thin film forming nozzle 1, the substrate placing stage 30, and the plurality of substrates 10 placed on the upper surface of the substrate placing stage 30 are accommodated in a film forming chamber 60. The film forming chamber 60 includes an upper chamber 68, a lower chamber 69, and a door 67. When the film forming chamber 60 performs film forming treatment, the film forming chamber 60 can isolate the thin film forming nozzle 1, the substrate placing stage 30, and the plurality of substrates 10 from the outside by closing the door 67 to close an opening portion between the upper chamber 68 and the lower chamber 69.

Thus, by closing the door 67 of the film forming chamber 60 and performing mist spray treatment using the thin film forming nozzle 1 during the heating treatment of the heating mechanism 32, a thin film can be formed on the substrates 10 placed on the upper surface of the substrate placing stage 30.

In this manner, a conventional film forming apparatus forms a thin film on the substrates 10 by simultaneously performing mist spray treatment using the thin film forming nozzle 1 and heating treatment using the heating mechanism 32.

### PRIOR ART DOCUMENTS

### Patent Documents

Patent Document 1: WO 2017/068625 A1

### SUMMARY

### Problem to be Solved by the Invention

As described above, generally, a conventional film forming apparatus has the following configuration. Specifically, the heating mechanism 32 is provided inside the substrate placing stage 30 that allows the substrates 10, which are base materials as a target of film formation, to be placed on its upper surface, and the substrate placing stage 30 is used as a flat heating means.

When a flat heating means such as the substrate placing stage 30 is used, heating treatment for the substrates 10 is performed by bringing the upper surface of the substrate placing stage 30 and the back surface of the substrates 10 to come in contact with each other and causing heat to be transferred between the substrate placing stage 30 and the substrates 10.

However, when the substrate 10 has such a structure that the lower surface of the substrate is curved or the lower surface has recessed portions and projecting portions, instead of having a flat plate-like shape, the flat heating means allows the upper surface of the substrate placing stage 3C) and the back surface of the substrates 10 to only locally come in contact with each other, Therefore, there have been problems in that heating of the substrates 10 is uneven when heating treatment is performed by the heating mechanism 32, and the substrates 10 are warped and deformed, for example.

The present invention has an object to solve the problems as described above, and provide a film forming apparatus that can form a thin film on a substrate at low costs without reducing film forming quality and a film forming rate.

### Means to Solve the Problem

A film forming apparatus according to the present invention includes: a substrate placing unit allowing a substrate to be placed thereon; a heating mechanism being provided apart from the substrate placing unit, including an infrared lamp, and being configured to perform heating treatment of heating the substrate by radiating infrared light from the infrared lamp; and a mist spray unit being configured to perform mist spray treatment of spraying source mist obtained by atomizing a source solution on front surface of the substrate. A thin film is formed on the front surface of the substrate by simultaneously performing the heating treatment of the heating mechanism and the mist spray treatment of the mist spray unit.

### Effects of the Invention

The film forming apparatus of the invention of the present application according to claim 1 includes the heating mechanism that is provided apart from the substrate placing unit and that performs heating treatment of heating the substrate by radiating infrared light from the infrared lamp.

Therefore, in the invention of the present application according to claim 1, the substrate can be directly heated by the heating mechanism without touching the substrate. Consequently, uniform heating can be performed without deforming the substrate, regardless of the shape of the substrate.

As a result, the film forming apparatus of the invention of the present application according to claim 1 can form a thin film on the substrate at low costs without reducing film forming quality and a film forming rate.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is an explanatory diagram illustrating a schematic configuration of a film forming apparatus according to a first embodiment of the present invention.

FIG. 2 is an explanatory diagram illustrating a schematic configuration of a film forming apparatus according to a second embodiment of the present invention.

FIG. 3 is an explanatory diagram illustrating a schematic configuration of a conventional film forming apparatus.

### DESCRIPTION OF EMBODIMENTS

### First Embodiment

FIG. 1 is an explanatory diagram illustrating a schematic configuration of a film forming apparatus according to the first embodiment of the present invention. An XYZ orthogonal coordinate system is illustrated in FIG. 1.

As illustrated in FIG. 1, a film forming apparatus 11 of the first embodiment includes a film forming chamber 6A, a thin film forming nozzle 1, an infrared radiation apparatus 2, and a conveyor 53 as main components.

The conveyor 53 being a substrate placing unit allows a plurality of substrates 10 to be placed on an upper surface of a belt 52. The conveyor 53 includes a pair of rollers 51 for conveyance provided at both right and left (−X direction, +X direction) ends, and an endless belt 52 for conveyance that is stretched across the pair of rollers 51.

With rotational drive of the pair of rollers 51, the conveyor 53 can move an upper side (+Z direction side) of the belt 52 along a conveying direction (X direction).

The pair of rollers 51 of the conveyor 53 is provided outside the film forming chamber 6A, and the belt 52 has a center portion being provided inside the film forming chamber 6A, and can be moved between the inside and the outside of the film forming chamber 6A through a pair of opening portions 63 provided at a portion of right and left (−X direction, +X direction) side surfaces of the film forming chamber 6A.

The thin film forming nozzle 1, a part of the conveyor 53, the plurality of substrates 10 placed on the upper surface of the belt 52 of the conveyor 53, and the infrared radiation apparatus 2 are accommodated in the film forming chamber 6A.

The film forming chamber 6A includes an upper chamber 61, a lower chamber 62, and a pair of opening portions 63. The pair of opening portions 63 is located between the upper chamber 61 and the lower chamber 62 in a height direction being the Z direction. Therefore, the conveyor 53 provided between the opening portions 63 and 63 in the film forming chamber 6A is disposed at a position higher than the lower chamber 62 and lower than the upper chamber 61.

The infrared radiation apparatus 2 being a heating mechanism is fixed at a position apart from the conveyor 53 in the lower chamber 62 by a fixing means (not shown).

Note that the infrared radiation apparatus 2 is disposed at a position overlapping the upper surface of the belt 52 in the film forming chamber 6A in plan view.

The infrared radiation apparatus 2 includes a lamp placing table 21 and a plurality of infrared lamps 22. The plurality of infrared lamps 22 are attached to an upper portion of the lamp placing table 21. Therefore, the infrared radiation apparatus 2 can radiate infrared light upwardly (+Z direction) from the plurality of infrared lamps 22. With the above-mentioned infrared radiation of the infrared radiation apparatus 2, heating treatment for the plurality of substrates 10 placed on the upper surface of the belt 52 can be performed.

The thin film forming nozzle 1 being a mist spray unit is fixedly disposed in the upper chamber 61 by a fixing means (not shown). In this case, the thin film forming nozzle 1 is disposed to have such a positional relationship that the spray surface 1S and the upper surface of the belt 52 face each other.

The thin film forming nozzle 1 performs mist spray treatment of spraying source mist MT downwardly (−Z direction) from a spray port provided in the spray surface 1S. Note that the source mist MT is a mist obtained by atomizing a source solution. Using the thin film forming nozzle 1, the source mist MT can be sprayed in the atmosphere.

The film forming chamber 6A can isolate the thin film forming nozzle 1, the plurality of substrates 10 placed on the belt 52, and the infrared radiation apparatus 2 from the outside by closing the opening portions 63 between the upper chamber 61 and the lower chamber 62 with an air curtain 7 when film forming treatment is performed.

Therefore, the film forming apparatus 11 of the first embodiment can set a film forming environment by closing the pair of opening portions 63 of the film forming chamber 6A with the air curtain 7 and moving the belt 52 of the conveyor 53 along the conveying direction (X direction).

Then, the film forming apparatus 11 forms a thin film on the substrates 10 placed on the upper surface of the belt 52 in the film forming chamber 6A by simultaneously performing the heating treatment of infrared radiation of the infrared radiation apparatus 2 and the mist spray treatment of the thin film forming nozzle 1 under the film forming environment.

As described above, the film forming apparatus 11 of the first embodiment includes the infrared radiation apparatus 2 that is provided apart from the conveyor 53 being a substrate placing unit, and that performs heating treatment of directly heating the plurality of substrates 10 by radiating infrared light from the infrared lamps 22 as a heating mechanism.

Thus, the film forming apparatus 11 of the first embodiment can directly heat the substrates 10 with the infrared radiation apparatus 2 without touching the substrates 10. Therefore, the film forming apparatus 11 of the first embodiment can perform uniform healing without deforming the substrates 10, regardless of the shape of the substrates 10.

As a result, the film forming apparatus 11 of the first embodiment can form a thin film on the substrates 10 at low costs without reducing film forming quality and a film forming rate.

Further, by providing the infrared radiation apparatus 2 being a heating mechanism inside the film forming chamber 6A, the film forming apparatus 11 of the first embodiment can radiate infrared light on the substrates 10 without through the film forming chamber 6A. Accordingly, the film forming apparatus 11 of the first embodiment can enhance efficiency of radiating infrared light.

Note that the radiation of infrared light from the infrared radiation apparatus 2 located below (−Z direction) the conveyor 53 is performed upwardly (+Z direction). This means that infrared light is radiated on the plurality of substrates 10 through the belt 52 (upper side and lower side) of the conveyor 53.

In consideration of such configurations, the first countermeasure and the second countermeasure are conceivable: The first countermeasure adopts a structure in which the belt 52 includes a combination of a pair of linear conveyor chains and an opening portion for transmission of infrared light is provided, and the second countermeasure adopts a configuration in which an infrared light transmitting material having excellent transmittance of infrared light that does not absorb infrared light is used as a constituent material of the belt 52.

Thus, regarding the belt 52, by adopting at least one countermeasure out of the first and second countermeasures, an infrared light absorption degree of the belt 52 can be reduced to a minimum necessary degree.

A specific example of the second countermeasure will be described below. Possible examples of the infrared light transmitting material include germanium, silicon, zinc sulfide, and zinc selenide. Note that it is necessary that strength for being used as the belt 52 be satisfied.

Further, regarding the wavelength of the infrared light radiated from the infrared radiation apparatus 2, it is desirable to adopt of a first modification in which the wavelength is set avoiding an absorption wavelength range of the source mist MT. As a specific setting for implementing the first modification, it is conceivable to set the wavelength of the infrared light radiated from the infrared radiation apparatus 2 to fall within a range of 700 to 900 nm. This is because, by adopting the above specific setting, the absorption wavelength range of the source mist MT using a possible solvent can be avoided.

It is confirmed as a known fact that, if water or toluene is used as a solvent of a source solution for forming a film, setting of the wavelength of the infrared light radiated from the infrared radiation apparatus 2 to fall within a range of 700 to 900 nm according to the above specific setting allows the wavelength to fall outside the absorption wavelength range of the source mist MT.

By adopting the first modification, the film forming apparatus 11 produces an effect of avoiding occurrence of a source mist evaporation phenomenon, in which the source mist MT absorbs infrared light radiated from the infrared radiation apparatus 2 so that the source mist MT is heated and evaporated.

Adopting the specific setting of setting the wavelength of the infrared light to range from 700 to 900 nm as the first modification in particular produces an effect of avoiding occurrence of the source mist evaporation phenomenon for the source mist MT made from any possible source material.

### Second Embodiment

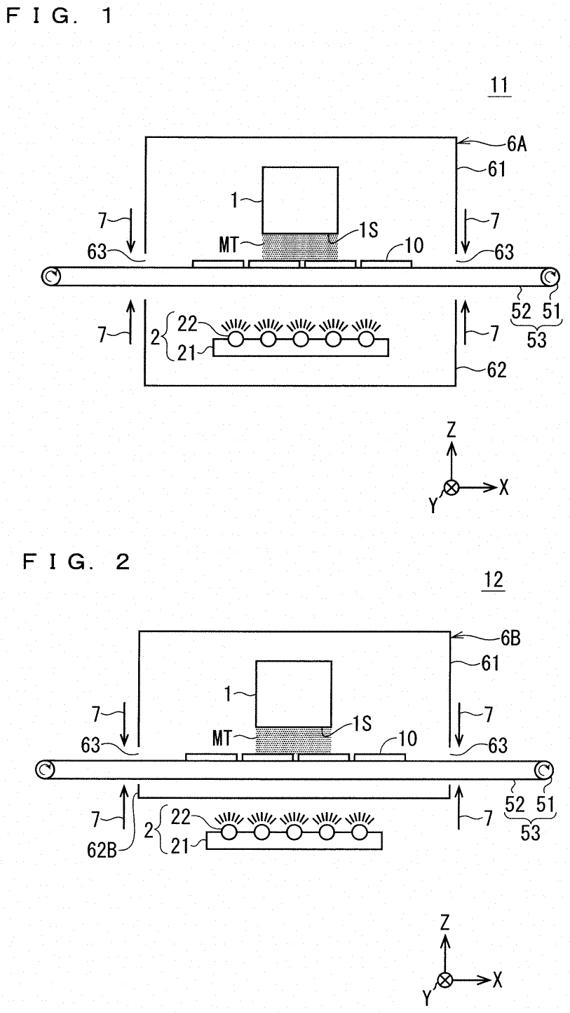

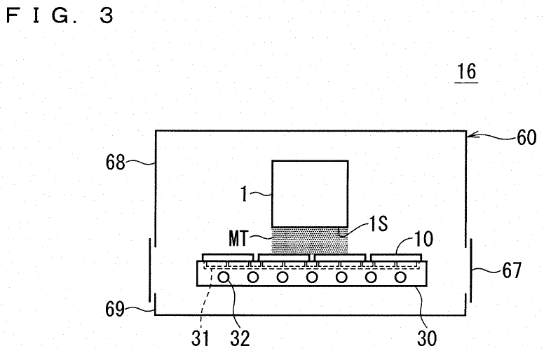

FIG. 2 is an explanatory diagram illustrating a schematic configuration of a film forming apparatus according to the second embodiment of the present invention. An XYZ orthogonal coordinate system is illustrated in FIG. 2.

As illustrated in FIG. 2, a film forming apparatus 12 of the second embodiment includes a film forming chamber 6B, a thin film forming nozzle 1, an infrared radiation apparatus 2, and a conveyor 53 as main components.

In the following, components common to those of the film forming apparatus 11 of the first embodiment are denoted by the same reference signs to appropriately omit description thereof, and features of the film forming apparatus 12 of the second embodiment will be mainly described.

The thin film forming nozzle 1, a part of the conveyor 53, and the plurality of substrates 10 placed on the upper surface of the belt 52 of the conveyor 53 are accommodated in the film forming chamber 6B. The film forming chamber 6B includes an upper chamber 61, a lower chamber 629, and a pair of opening portions 63, and the pair of opening portions 63 is provided at a portion of right and left side surfaces of the film forming chamber 6B. Note that the pair of opening portions 63 is located between the upper chamber 61 and the lower chamber 62B in the height direction being the Z direction.

The film forming chamber 6B has, as its constituent material, an infrared light transmitting material having excellent transmittance that does not absorb infrared light radiated from the infrared radiation apparatus 2. Specifically, the film forming chamber 6B has quartz glass as its constituent material.

The infrared radiation apparatus 2 being a heating mechanism is fixed below (−Z direction) and outside the lower chamber 62B at a position apart from the conveyor 53 by a fixing means (not shown).

Note that the infrared radiation apparatus 2 is disposed at a position overlapping the upper surface of the belt 52 in the film forming chamber 6B in plan view.

By radiating infrared light upwardly from the plurality of infrared lamps 22, the infrared radiation apparatus 2 can perform heating treatment for the plurality of substrates 10 placed on the upper surface of the belt 52 through the lower chamber 62B and the belt 52.

The film forming chamber 6B can isolate the thin film forming nozzle 1 and the plurality of substrates 10 placed on the belt 52 from the outside by closing the opening portions 63 between the upper chamber 61 and the lower chamber 62B with the air curtain 7 when film forming treatment is performed.

Therefore, the film forming apparatus 12 of the second embodiment can set a film forming environment by closing the pair of opening portions 63 of the film forming chamber 6B with the air curtain 7 and moving the belt 52 of the conveyor 53 in the conveying direction (X direction).

Then, the film forming apparatus 12 forms a thin film on the substrates 10 placed on the upper surface of the belt 52 in the film forming chamber 6B by simultaneously performing the heating treatment of infrared radiation of the infrared radiation apparatus 2 and the mist spray treatment of the thin film forming nozzle 1 under the film forming environment.

As described above, the film forming apparatus 12 of the second embodiment includes the infrared radiation apparatus 2 that is provided apart from the belt 52 being a substrate placing unit, and that performs heating treatment of heating the plurality of substrates 10 by radiating infrared light from the infrared lamps 22 as a heating mechanism.

Thus, similarly to the first embodiment, the film forming apparatus 12 of the second embodiment can heat the substrates 10 with the infrared radiation apparatus 2 without touching the substrates 10. Therefore, the film forming apparatus 12 of the second embodiment can perform uniform heating without deforming the substrates 10, regardless of the shape of the substrates 10.

As a result, similarly to the first embodiment, the film forming apparatus 12 of the second embodiment can form a thin film on the substrates 10 at low costs without reducing film forming quality and a film forming rate.

Further, by providing the infrared radiation apparatus 2 outside the film forming chamber 6B, the film forming apparatus 12 of the second embodiment can simplify maintenance of the infrared radiation apparatus 2, such as replacement of the infrared lamps 22.

In addition, the film forming chamber 6B of the film forming apparatus 12 of the second embodiment has, as its constituent material, quartz glass being an infrared light transmitting material having excellent transmittance for infrared light radiated from the infrared lamps 22. This configuration produces an effect of reducing an infrared light absorption degree of the bottom surface of the lower chamber 62 at the time of heating the substrates 10 through the bottom surface of the lower chamber 62 of the film forming chamber 6B to a minimum necessary degree.

Note that, when quartz glass being an infrared light transmitting material is used at least as a constituent material of the bottom surface of the lower chamber 62B of the film forming chamber 6B, the above effect can be produced.

Further, other than quartz glass, the following materials are conceivable as the infrared light transmitting material, for example. Materials such as borosilicate sapphire, calcium fluoride, barium fluoride, magnesium fluoride, and lithium fluoride have high transmittance for near infrared light, and are thus conceivable as an infrared light transmitting material other than quartz glass. Specifically, it is only necessary that the constituent material of the film forming chamber 6B contain at least one of quartz glass, borosilicate glass, sapphire, calcium fluoride, barium fluoride, magnesium fluoride, and lithium fluoride.

Note that, in the film forming apparatus 12 of the second embodiment as well, similarly to the first embodiment, at least one countermeasure out of the first and second countermeasures related to infrared light absorption of the belt 52 may be adopted.

Further, in the film forming apparatus 12 of the second embodiment, similarly to the first embodiment, the first modification (including the specific setting described in the first embodiment) may be adopted regarding the wavelength of the infrared light radiated from the infrared radiation apparatus 2.

Note that, in the present invention, each embodiment can be freely combined or each embodiment can be modified or omitted as appropriate within the scope of the invention.

While the invention has been shown and described in detail, the foregoing description is in all aspects illustrative and not restrictive. It is therefore understood that numerous unillustrated modifications and variations can be devised without departing from the scope of the invention.

### EXPLANATION OF REFERENCE SIGNS

1 Thin film forming nozzle
2 Infrared radiation apparatus
11, 12 Film forming apparatus
21 Lamp placing table
22 Infrared lamp
6A, 6B Film forming chamber
51 Roller
52 Belt
53 Conveyor
61 Upper chamber
62, 62B Lower chamber
63 Opening portion

1. A film forming apparatus comprising:
a substrate placing unit allowing a substrate to be placed thereon;
a heating mechanism provided apart from said substrate placing unit, including an infrared lamp, and configured to perform heating treatment of heating said substrate by radiating infrared light from said infrared lamp; and
a mist spray unit configured to perform mist spray treatment of spraying source mist obtained by atomizing a source solution on a front surface of said substrate, wherein
a thin film is formed on the front surface of said substrate by simultaneously performing said heating treatment of said heating mechanism and said mist spray treatment of said mist spray unit.

2. The film forming apparatus according to claim 1, further comprising
a film forming chamber configured to internally accommodate said substrate, said heating mechanism, and said mist spray unit.

3. The film forming apparatus according to claim 1, further comprising
a film forming chamber configured to internally accommodate said substrate and said mist spray unit, wherein
said heating mechanism is disposed outside said film forming chamber, and performs said heating treatment by through said film forming chamber, and
said film forming chamber has an infrared light transmitting material having excellent transmittance for infrared light radiated from said infrared lamp of said heating mechanism as a constituent material.

4. The film forming apparatus according to claim 3, wherein
said infrared light transmitting material contains at least one of quartz glass, borosilicate glass, sapphire, calcium fluoride, barium fluoride, magnesium fluoride, and lithium fluoride.
